(19) United States
(12) Patent Application Publication
(10) Pub. No.: US 2012/0098143 A1
(43) Pub. Date: Apr. 26, 2012

(54) METHOD FOR PACKAGING A SEMICONDUCTOR CHIP, AND SEMICONDUCTOR PACKAGE

(76) Inventor: Tsung-Chi WANG, Taipei City (TW)

(21) Appl. No.: 13/278,646

(22) Filed: Oct. 21, 2011

(30) Foreign Application Priority Data
Oct. 22, 2010 (TW) 099136258

(51) Int. Cl. H01L 23/48; H01L 21/50

(52) U.S. Cl. 257/774; 438/113; 257/E21.499; 257/E23.011

(57) ABSTRACT

A method for packaging a semiconductor chip includes: providing a semiconductor wafer that has an upper surface and includes a plurality of chip regions, each of the chip regions having a semiconductor unit that includes at least one electrical-connecting pad; forming over the upper surface a photoresist layer, followed by forming a plurality of pad-exposing holes in the photoresist layer; filling a first conductive material in the pad-exposing holes, followed by reflowing; removing the photoresist layer, and forming over the upper surface a protective layer; grinding the protective layer; coating an insulated protective layer on the ground protective layer, and forming a plurality of via holes in the insulated protective layer; filling a second conductive material in the via holes, followed by reflowing; and removing the insulated protective layer.

### CROSS-REFERENCE TO RELATED APPLICATION

This application claims priority of Taiwanese application no. 099136258, filed on Oct. 22, 2010.

### BACKGROUND OF THE INVENTION

1. Field of the Invention

The present invention relates to a method for packaging a semiconductor chip and to a semiconductor package.

2. Description of the Related Art

Conventionally, a method for forming a solder ball on a bonding pad of a semiconductor chip includes generally applying a solder layer first on the bonding pad of the semiconductor chip. The solder layer on the bonding pad is then formed into a solder bail through a reflowing treatment. However, such a manufacturing method has disadvantages that the solder ball is likely to separate from the bonding pad of the semiconductor chip, and the height of the solder ball which is measured from a surface of the semiconductor chip to a top end of the solder ball is difficult to be controlled, thereby resulting in poor electrical connection or even no electrical connection between the semiconductor chip and an external circuit. In addition, formation of a solder ball on a single chip is time-consuming and results in poor yield.

### SUMMARY OF THE INVENTION

Therefore, the object of the present invention is to provide a method for packaging a semiconductor chip and a semiconductor package.

According to an aspect of the present invention, a method for packaging a semiconductor chip is provided. The method comprises: providing a semiconductor wafer that has an upper surface and includes a plurality of chip regions, each of the chip regions having a semiconductor unit that includes at least one electrical-connecting pad formed on the upper surface; forming over the upper surface a photoresist layer to cover all of the chip regions, the photoresist layer being subjected to exposing and developing treatments to form a plurality of pad-exposing holes each of which exposes the electrical-connecting pad of a respective one of the chip regions; filling a first conductive material in the pad-exposing holes of the photoresist layer, followed by reflowing so as to form the first conductive material into a plurality of first electrical contacts respectively in the pad-exposing holes; removing the photoresist layer, and forming over the upper surface a protective layer to cover all of the first electrical contacts; grinding the protective layer until a top end of each of the first electrical contacts is exposed; coating an insulated protective layer on the ground protective layer, the insulated protective layer being subjected to exposing and developing treatments to form a plurality of via holes to expose the first electrical contacts; filling a second conductive material in the via holes, followed by reflowing so as to form the second conductive material into a plurality of second electrical contacts that are respectively located in the via holes and respectively connected to the first electrical contacts; and removing the insulated protective layer.

According to another aspect of the present invention, a method for packaging a semiconductor chip is provided. The method comprises: providing a semiconductor wafer that has upper and lower surfaces and includes a plurality of chip regions, each of the chip regions having a semiconductor unit that includes: at least one electrical-connecting pad formed on the upper surface, at least one metal pad formed on the lower surface, and, at least one through hole extending through the semiconductor unit to spatially communicate the electrical-connecting pad and the metal pad; filling a first conductive material in the through hole of the semiconductor unit of each of the chip regions; performing a reflowing treatment to form the first conductive material into a plurality of first electrical contacts each of which protrudes out of the metal pad of a respective one of the chip regions; forming over the lower surface a protective layer to cover all of the first electrical contacts; grinding the protective layer until a lower end of each of the first electrical contacts is exposed; coating an insulated protective layer on the ground protective layer, the insulated protective layer being subjected to exposing and developing treatments to form a plurality of via holes to expose the first electrical contacts; filling a second conductive material in the via holes, followed by reflowing so as to form the second conductive material into a plurality of second electrical contacts that are respectively located in the via holes and respectively connected to the first electrical contacts; and removing the insulated protective layer.

According to still another aspect of the present invention, a method for packaging a semiconductor chip is provided. The method comprises: providing a semiconductor wafer that has an upper surface and includes a plurality of chip regions, each of the chip regions having a semiconductor unit that includes at least one electrical-connecting pad formed on the upper surface; forming over the upper surface a photoresist layer to cover all of the chip regions, the photoresist layer being subjected to exposing and developing treatments to form a plurality of pad-exposing holes each of which exposes the electrical-connecting pad of a respective one of the chip regions; filling a first conductive material in the pad-exposing holes of the photoresist layer, followed by reflowing so as to form the first conductive material into a plurality of first electrical contacts respectively in the pad-exposing holes; grinding the photoresist layer until a top end of each of the first electrical contacts is exposed; coating an insulated protective layer on the ground photoresist layer, the insulated protective layer being subjected to exposing and developing treatments to form a plurality of via holes to expose the first electrical contacts; filling a second conductive material in the via holes, followed by reflowing so as to form the second conductive material into a plurality of second electrical contacts that are respectively located in the via holes and respectively connected to the first electrical contacts; and removing the insulated protective layer.

According to yet another aspect of the present invention, a semiconductor package is provided. The semiconductor package comprises: a semiconductor unit including an upper surface and at least one electrical-connecting pad formed on the upper surface; a protective layer formed on the upper surface of the semiconductor unit, and formed with at least one pad-exposing hole to expose the electrical-connecting pad; at least one first electrical contact that is received in the pad-exposing hole and that is connected to the electrical-connecting pad; and at least one second electrical contact farmed on the protective layer and immediately above the first electrical contact.

### BRIEF DESCRIPTION OF THE DRAWINGS

Other features and advantages of the present invention will become apparent in the following detailed description of the preferred embodiments with reference to the accompanying drawings, of which:

FIGS. 1 to 10 are schematic diagrams illustrating consecutive steps of the first preferred embodiment of a method for packaging a semiconductor chip according to the present invention;

FIGS. 11 to 13 are schematic diagrams illustrating some steps of the second preferred embodiment of a method for packaging a semiconductor chip according to the present invention;

FIG. 14 is a fragmentary partly sectional view illustrating mounting of a semiconductor package made by the first or second preferred embodiment on a carrier;

FIGS. 15 to 24 are schematic diagrams illustrating consecutive steps of the third preferred embodiment of a method for packaging a semiconductor chip according to the present invention;

FIG. 25 is a partly sectional view illustrating the semiconductor packages made by the third preferred embodiment in a stacked configuration; and

FIGS. 26 to 33 are schematic diagrams illustrating consecutive steps of the fourth preferred embodiment of a method for packaging a semiconductor chip according to the present invention.

### DETAILED DESCRIPTION OF THE PREFERRED EMBODIMENTS

Before the present invention is described in greater detail, it should be noted that like components are assigned the same reference numerals throughout the following disclosure. In addition, in order to illustrate clearly the features of the present invention, the components in the drawings may not be drawn in actual scale.

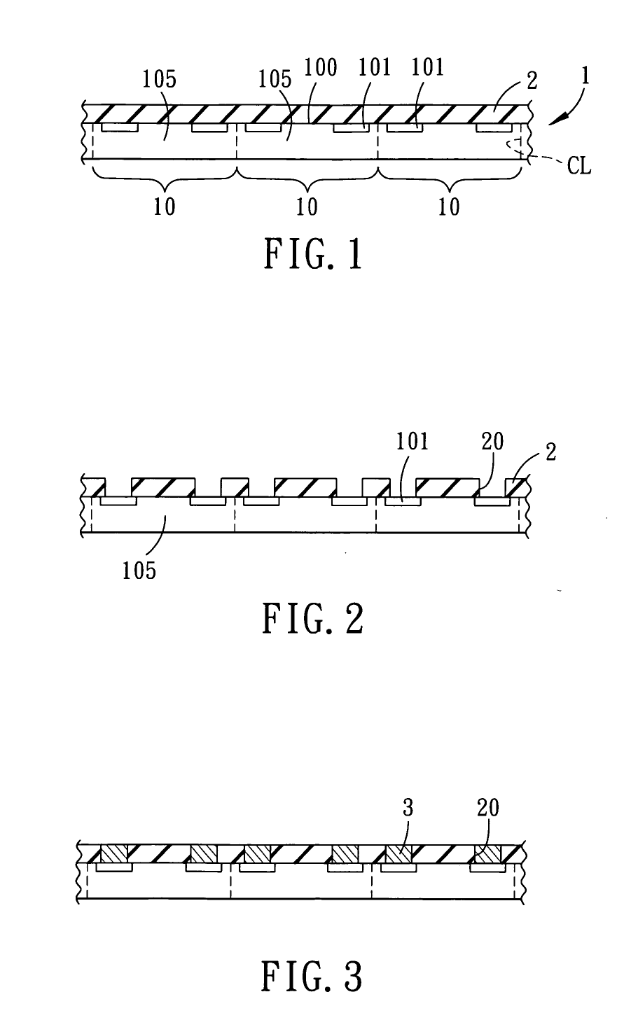

FIGS. 1 to 10 are schematic diagrams for illustrating the first preferred embodiment of a method for packaging a semiconductor chip according to the present invention.

Referring to FIGS. 1 to 10, at first, a semiconductor wafer 1 is provided. The semiconductor wafer 1 has an upper surface 100 and includes a plurality of chip regions 10. Each of the chip regions 10 has a semiconductor unit 105 that includes at least one electrical-connecting pad 101 formed on the upper surface 100 far electrical connection with an external circuit (not shown). In this embodiment, the upper surface 100 of the semiconductor wafer 1 corresponds to an upper surface of each of the semiconductor units 105.

Then, a photoresist layer 2 is formed on the upper surface 100 to cover all of the chip regions 10.

Referring to FIG. 2, the photoresist layer 2 is subjected to exposing and developing treatments to form a plurality of pad-exposing holes 20 each of which exposes the electrical-connecting pad 101 of a respective one of the chip regions 10.

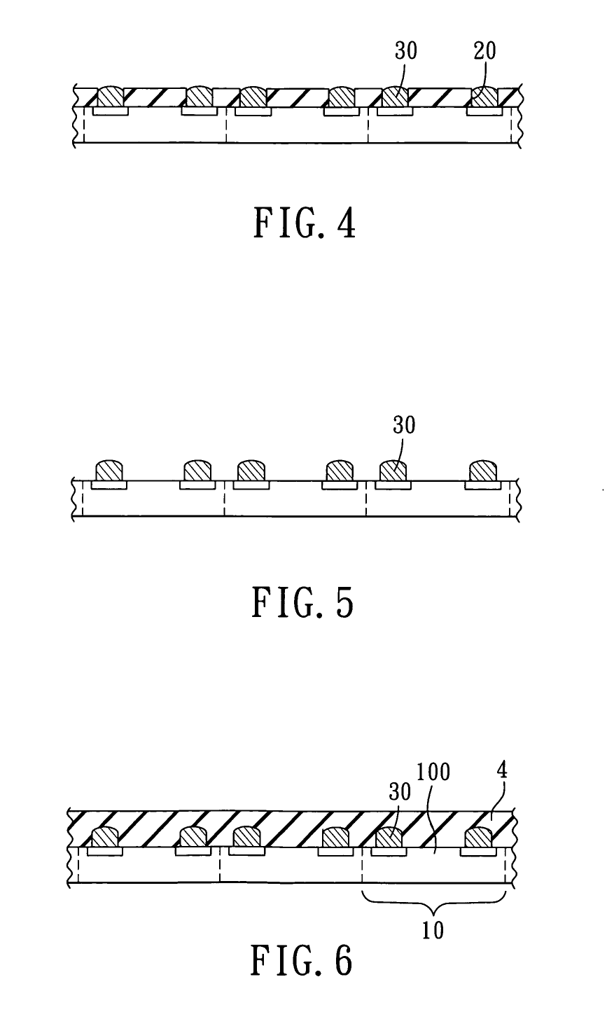

Next, a first conductive material 3 is filled in the pad-exposing holes 20 of the photoresist layer 2 by any suitable means (see FIG. 3), followed by reflowing so as to form the first conductive material 3 into a plurality of first electrical contacts 30 respectively in the pad-exposing holes 20, as shown in FIG. 4. In this embodiment, the first conductive material 3 is preferably a solder paste, and each of the first electrical contacts 30 has an arcuate end (see FIG. 4). The arcuate end of each of the first electrical contacts 30 partly protrudes beyond an upper surface of the photoresist layer 2.

Next, the photoresist layer 2 is removed by a stripping process, as shown in FIG. 5.

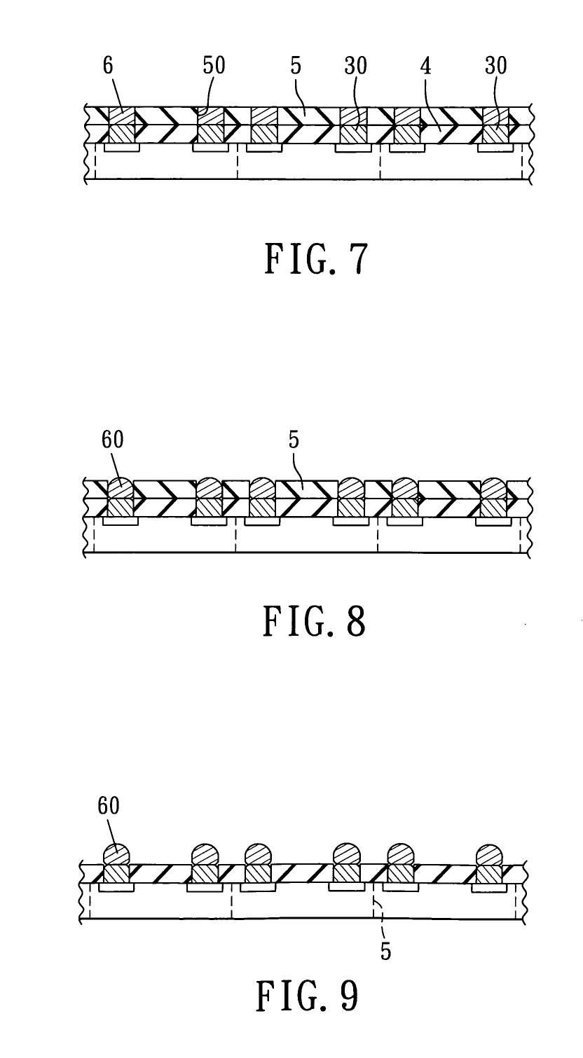

Referring to FIGS. 6 and 7, after the photoresist layer 2 is removed, a protective layer 4 is formed over the upper surface 100 to cover all of the first electrical contacts 30, followed by grinding the protective layer 4 and the first electrical contacts 30 until a flat end of each of the first electrical contacts 30 is exposed. To be specific, in this embodiment, the arcuate end is ground to form the flat end.

It is noted that short circuit between two adjacent first electrical contacts 30 can be avoided by the protective layer 4. In addition, in this embodiment, the protective layer 4 is preferably made of a transparent material.

Next, an insulated protective layer 5 is coated on the ground protective layer 4. The insulated protective layer 5 is subjected to exposing and developing treatments to form a plurality of via holes 50 to expose the first electrical contacts 30, followed by filling a second conductive material 6 in the via holes 50. In this embodiment, the second conductive material 6 is preferably a solder paste that is the same as the first conductive material 3.

Referring to FIG. 8, after a reflowing treatment, the second conductive material 6 is formed into a plurality of second electrical contacts 60 that are respectively located in the via holes 50 and respectively connected to the first electrical contacts 30. Each of the second electrical contacts 60 is formed with an arcuate end. The second electrical contacts 60 are not formed in the pad-exposing holes 20 and are formed immediately above the respective first electrical contacts 30.

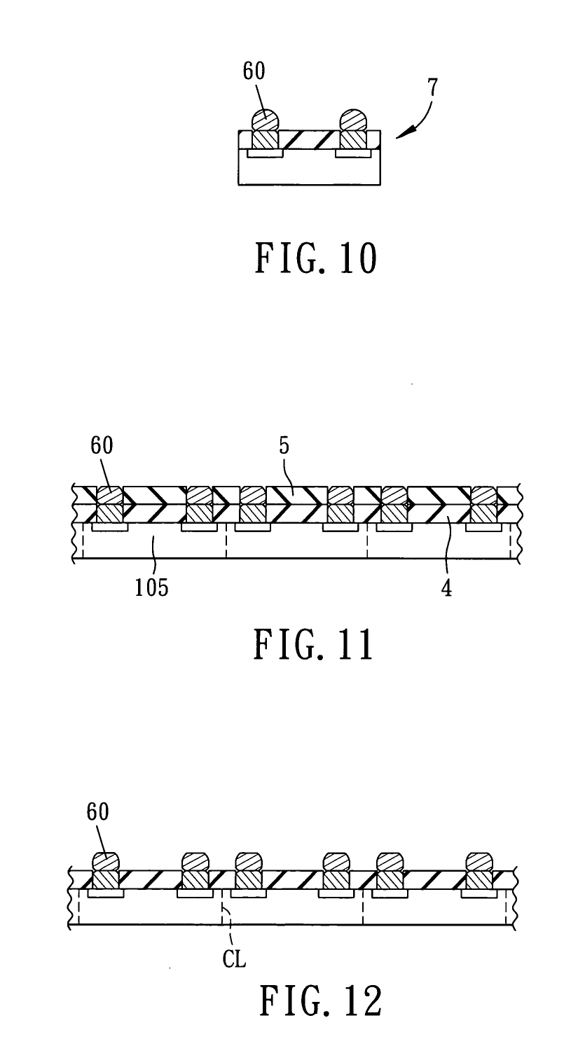

Finally, the insulated protective layer 5 is removed, as shown in FIG. 9. The semiconductor wafer 1 shown in FIG. 9 can be then formed into a plurality of semiconductor packages 7 by cutting the semiconductor wafer 1 along cutting lines (CL). FIG. 10 shows the semiconductor package 7 which is obtained by the aforesaid first preferred embodiment of the present invention and which can be mounted directly on a carrier, such as a circuit board (not shown).

It is noted that since the semiconductor unit 105 of each of the chip regions 10 has the upper surface 100 formed with at least one electrical-connecting pad 101, the method of the present invention can be applied to form any type of semiconductor packages, including but not limited to, diodes, light emitting diodes, central processing units, RFIDs, and/or TFT driver ICs. In addition, the formation of the second electrical contacts 60 enables an increase in the distance between the upper surface 100 and the carrier when the semiconductor packages 7 are mounted on the carrier, so that the yield of mounting the semiconductor packages on the carrier can be enhanced.

Further, since the heights of the photoresist layer 2 and the insulated protective layer 5 can be precisely controlled, the depths of the pad-exposing holes 20 and the via holes 50 can be precisely controlled. Therefore, the heights of the electrical contacts 30 and 60 can also be precisely controlled so as to equalize the height of each of the electrical contacts 30 and 60. In addition, the grinding step facilitates obtaining the electrical contacts 30 and 60 with equal heights.

FIGS. 11 to 13 are schematic diagrams for illustrating some steps of the second preferred embodiment of a method for packaging a semiconductor chip according to the present invention.

Referring to FIGS. 11 and 12, the second preferred embodiment of the method for packaging a semiconductor chip according to the present invention is similar to the first preferred embodiment except that after the second electrical contacts 60 are formed, the insulated protective layer 5 is formed on the surface of the protective layer 4 to cover all of the second electrical contacts 60. The insulated protective layer 5 is ground until a flat end of each of the second electrical contacts 60 is exposed. To be specific, in this embodiment, the arcuate end of each of the second electrical contacts 60 is ground to form the fiat end of each of the second electrical contacts 60. Finally, the insulated protective layer 5 is completely removed.

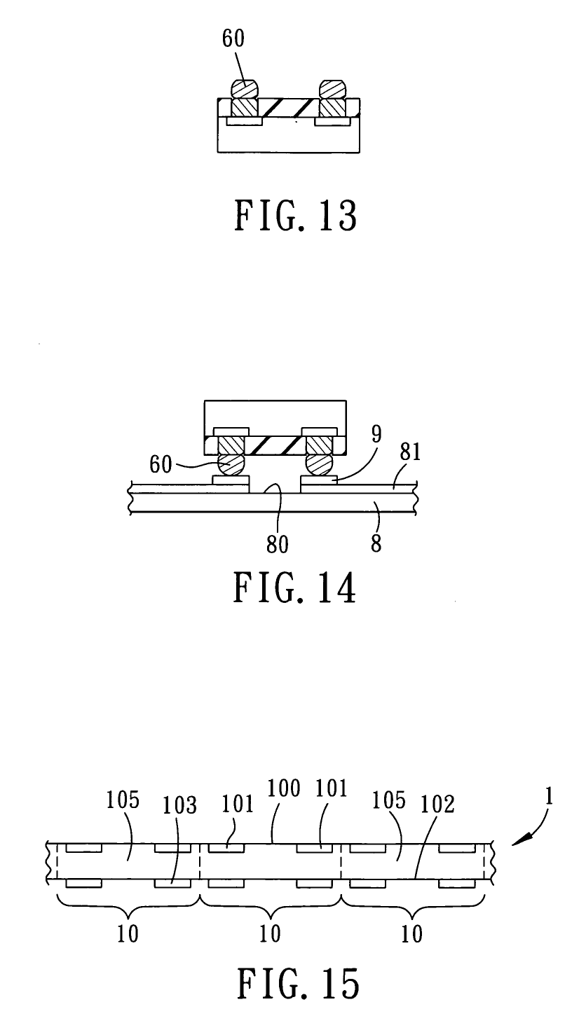

The semiconductor wafer 1 shown in FIG. 12 can be then formed into a plurality of semiconductor packages by cutting along cutting lines (CL) on the semiconductor wafer 1 (see FIG. 13). The semiconductor package can be mounted directly on a carrier, such as a circuit board (not shown).

FIG. 14 is a fragmentary partly sectional view illustrating the semiconductor package made through the first or second preferred embodiment and mounted on a printed circuit board 8.

As shown in FIG. 14, the printed circuit board 8 as the carrier has a circuit trace forming surface 80 and a plurality of circuit traces 81 formed on the forming surface 80. A conductive material 9 such as a solder paste is coated on the circuit traces 81 for electrical connection to the corresponding second electrical contacts 60 of the semiconductor package. The semiconductor package is then mounted on the forming surface 80 of the printed circuit board 8 so that the second electrical contacts 60 correspond to the conductive material 9 in position. Next, the second electrical contacts 60 of the semiconductor package can be connected electrically and firmly to the circuit traces 81 of the printed circuit board B by reflowing treatment.

FIGS. 15 to 24 are schematic diagrams for illustrating the third preferred embodiment of a method for packaging a semiconductor chip according to the present invention.

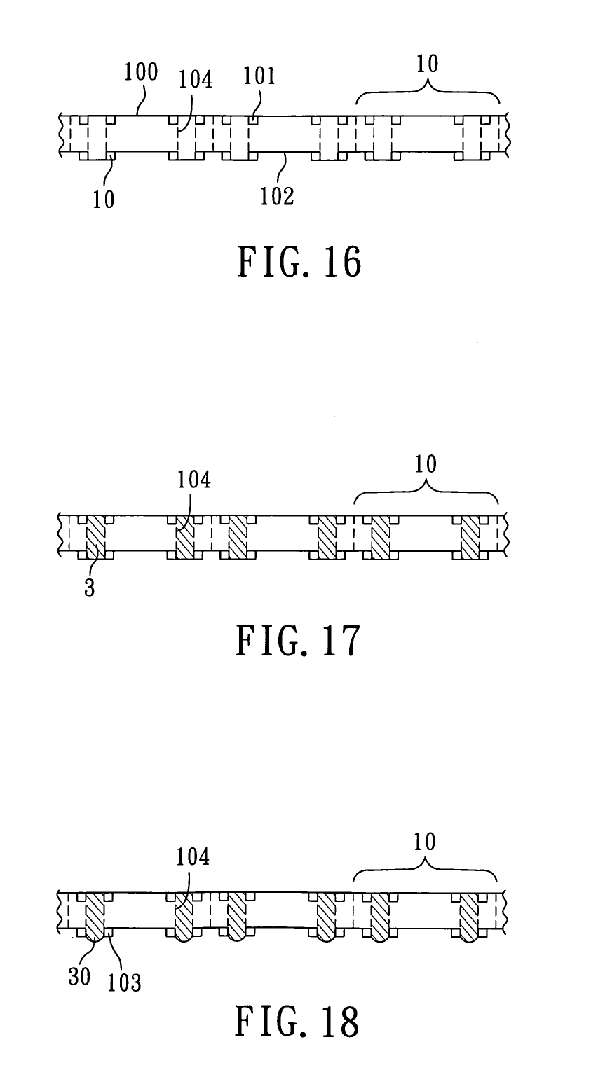

Referring to FIGS. 15 and 16, similar to the first preferred embodiment, at first, a semiconductor wafer 1 is provided. The wafer 1 has upper and lower surfaces 100, 102 and includes a plurality of chip regions 10. Each of the chip regions 10 has a semiconductor unit 105 that includes at least one electrical-connecting pad 101 formed on the upper surface 100, at least one metal pad 103 formed on the lower surface 102, and at least one through hole 104 extending through the semiconductor unit 105 to spatially communicate the electrical-connecting pad 101 and the metal pad 103.

Next, a first conductive material 3 is filled in the through hole 104 of the semiconductor unit 105 of each of the chip regions 10 (see FIG. 17) In this embodiment, the first conductive material 3 is preferably a solder paste.

Referring to FIG. 18, a reflowing treatment is performed to form the first conductive material 3 into a plurality of first electrical contacts 30 each of which protrudes out of the metal pad 103 of a respective one of the chip regions 10.

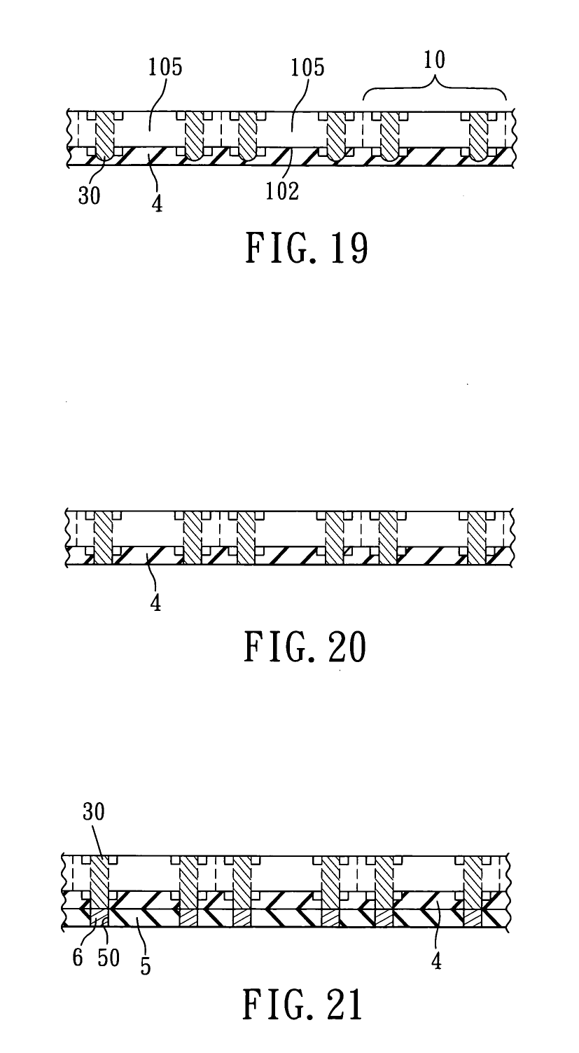

Next, a protective layer 4 is formed over the lower surface 102 to cover all of the first electrical contacts 30 (see FIG. 19), followed by grinding the protective layer 4 until a lower end of each of the first electrical contacts 30 is exposed (see FIG. 20). It is noted that the lower end of each of the first electrical contacts 30 is flush with a ground surface of the protective layer 4. In this embodiment, the protective layer 4 is made of a transparent material.

Referring to FIG. 21, an insulated protective layer 5 is then coated on the ground protective layer 4. The insulated protective layer 5 is subjected to exposing and developing treatments to form a plurality of via holes 50 to expose the first electrical contacts 30, followed by filling a second conductive material 6 in the via holes 50. In this embodiment, the second conductive material 6 is preferably a solder paste that is the same as the first conductive material 3.

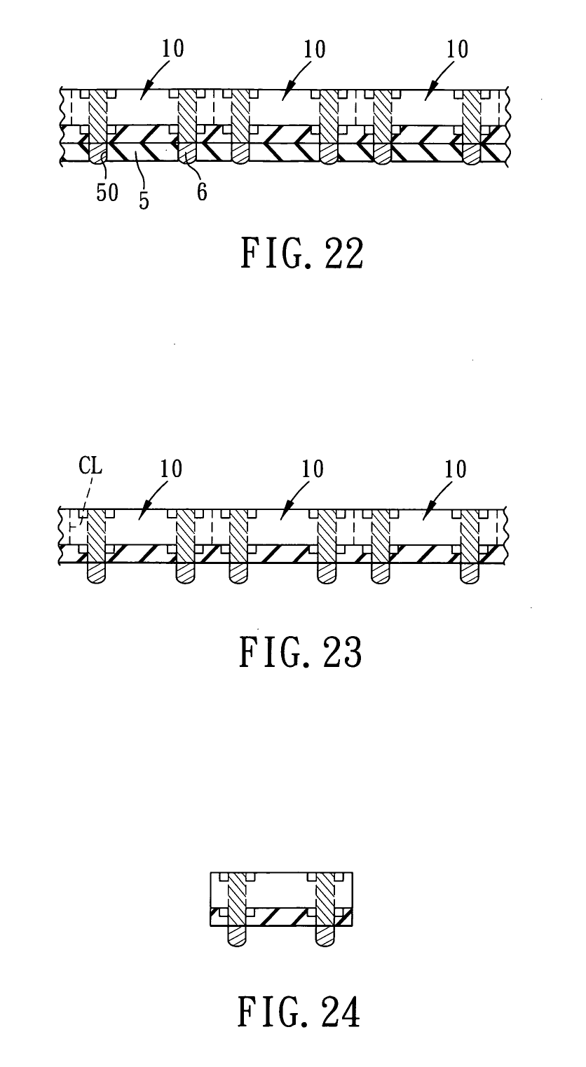

Referring to FIG. 22, after a reflowing treatment, the second conductive material 6 is formed into a plurality of second electrical contacts 60 that are respectively located in the via holes 50 and respectively connected to the first electrical contacts 30. Each of the second electrical contacts 60 is formed with an arcuate end.

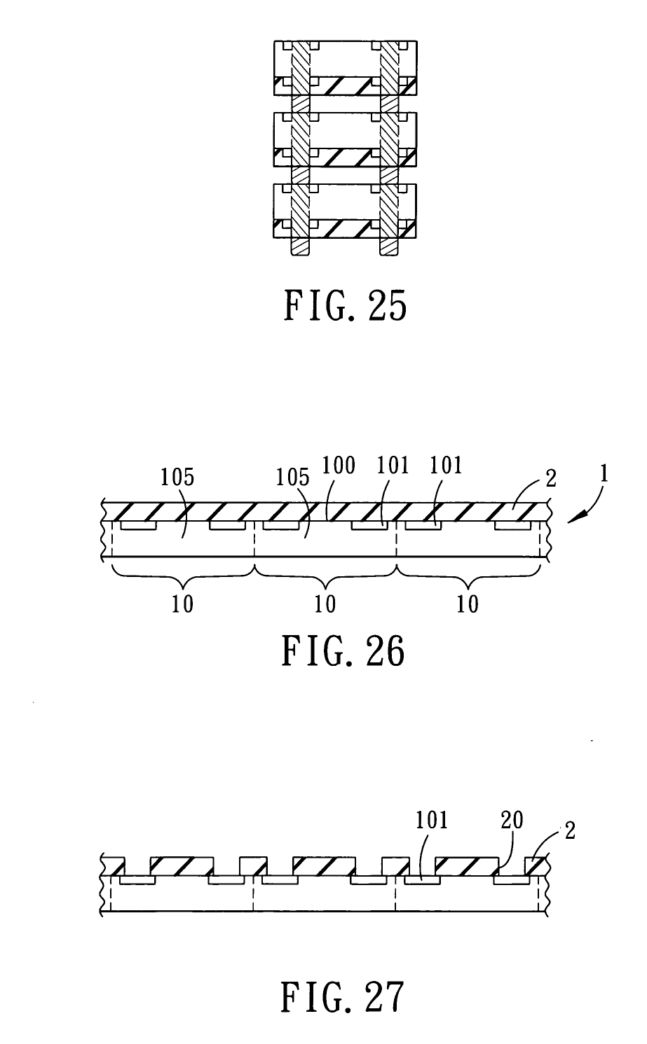

Finally, the insulated protective layer 5 is removed, as shown in FIG. 23. The semiconductor wafer 1 shown in FIG. 23 can be then formed into a plurality of semiconductor packages by cutting the semiconductor wafer 1 along cutting lines (CL). FIG. 24 shows the semiconductor package which is obtained through the aforesaid third preferred embodiment of the present invention and which can be mounted directly on a carrier, such as a circuit board (not shown). The semiconductor packages thus obtained can be arranged in a stack configuration, as best illustrated in FIG. 25, and the stacked semiconductor packages are then mounted on a carrier (not shown). Of course, one of the semiconductor packages may be first mounted on a carrier and the other semiconductor packages may then be stacked on the semiconductor package already mounted on the carrier.

It is noted that the third preferred embodiment of the method for packaging a semiconductor chip according to the present invention may further comprise, before removing the insulated protective layer 5, a step of grinding the insulated protective layer 5 and the second electrical contacts 60 so that a lower end of each of the second electrical contacts 60 is flush with a ground surface of the insulated protective layer 5.

FIGS. 26 to 33 are schematic diagrams for illustrating the fourth preferred embodiment of a method for packaging a semiconductor chip according to the present invention.

Referring to FIG. 26, a semiconductor wafer 1 is provided. The wafer 1 has an upper surface 100 and includes a plurality of chip regions 10. Each of the chip regions 10 has a semiconductor unit 105 that includes at least one electrical-connecting pad 101 formed on the upper surface 100 for electrical connection with an external circuit (not shown). In this embodiment, the upper surface 100 of the semiconductor wafer 1 corresponds to an upper surface of each of the semiconductor units 105.

Then, a photoresist layer 2 is formed on the upper surface 100 to cover all of the chip regions 10.

Referring to FIG. 27, the photoresist layer 2 is subjected to exposing and developing treatments to form a plurality of pad-exposing holes 20 each of which exposes the electrical-connecting pad 101 of a respective one of the chip regions 10.

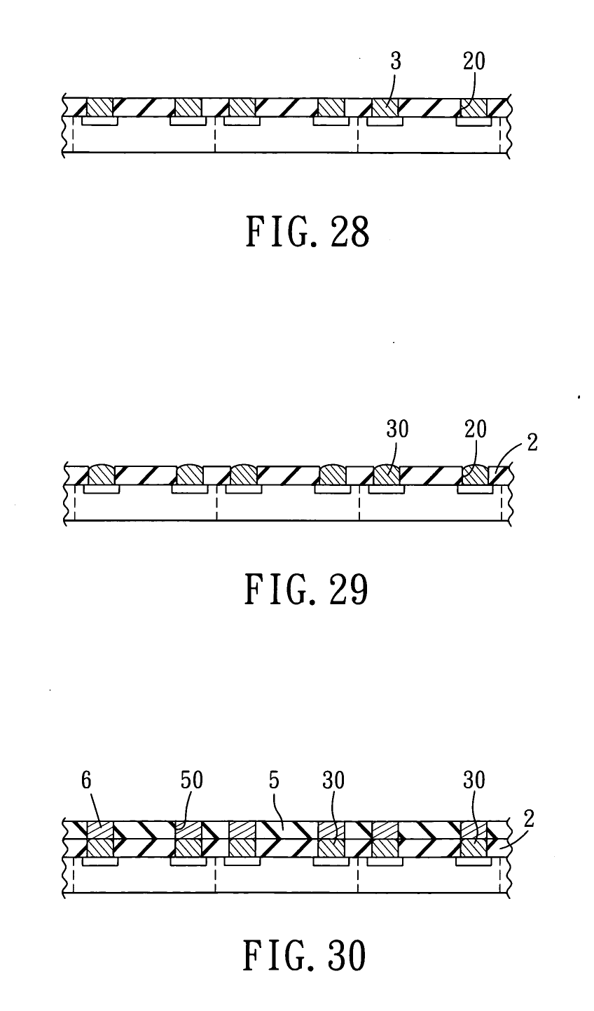

Next, a first conductive material 3 is filled in the pad-exposing holes 20 of the photoresist layer 2 by any suitable means (see FIG. 28), followed by reflowing so as to form the first conductive material 3 into a plurality of first electrical contacts 30 respectively in the pad-exposing holes 20, as shown in FIG. 29. In this embodiment, the first conductive material 3 is preferably a solder paste. Each of the first electrical contacts 30 has an arcuate end, as best illustrated in FIG. 29.

Next, referring to FIG. 30, the photoresist layer 2 is ground and the arcuate end of each of the first electrical contacts 30 is also ground to become a flat end.

An insulated protective layer 5 is then coated on the ground photoresist layer 2. The insulated protective layer 5 is subjected to exposing and developing treatments to form a plurality of via holes 50 to expose the first electrical contacts 30, followed by filling a second conductive material 6 in the via holes 50. In this embodiment, the second conductive material 6 is preferably a solder paste that is the same as the first conductive material 3.

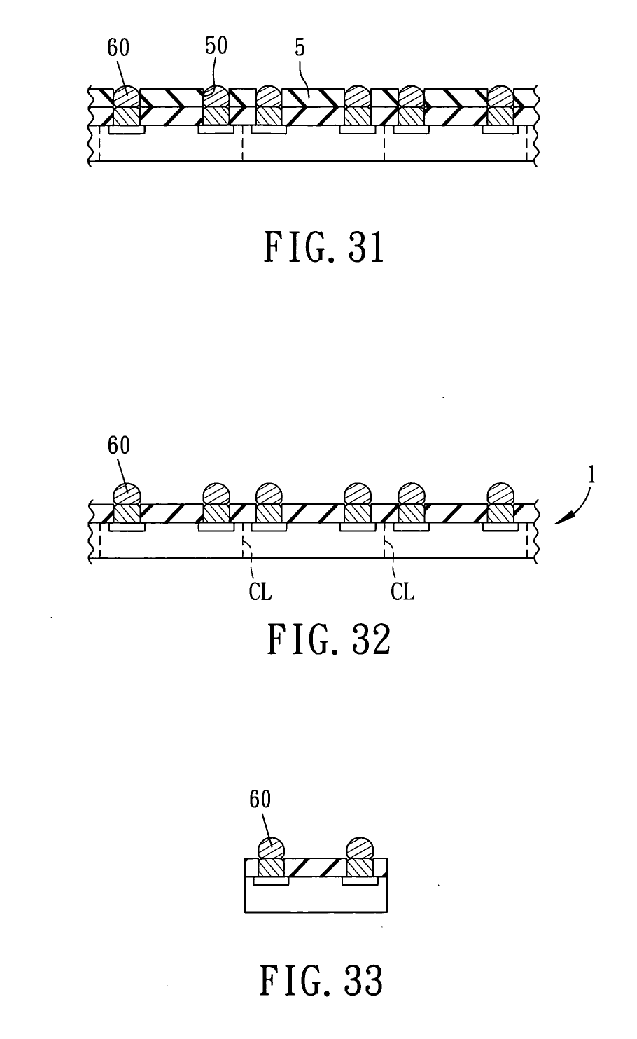

Referring to FIG. 31, after a reflowing treatment, the second conductive material 6 is formed into a plurality of second electrical contacts 60 that are respectively located in the via holes 50 and respectively connected to the first electrical contacts 30. Each of the second electrical contacts 60 is formed with an arcuate end. The second electrical contacts 60 are not formed in the pad-exposing holes 20 and are formed immediately above the respective first electrical contacts 30.

Finally, the insulated protective layer 5 is removed, as shown in FIG. 32. The semiconductor wafer 1 shown in FIG. 32 can be then formed into a plurality of semiconductor packages by cutting the semiconductor wafer 1 along cutting lines (CL). FIG. 33 shows the semiconductor package which is obtained through the aforesaid fourth preferred embodiment of the present invention and which can be mounted directly on a carrier, such as a circuit board (not shown).

It is noted that the fourth preferred embodiment of the method for packaging a semiconductor chip according to the present invention may further comprise, before removing the insulated protective layer 5, a step of grinding the insulated protective layer 5 and the second electrical contacts 60 so that a top end of each of the second electrical contacts 60 is flush with a ground surface of the insulated protective layer 5.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A method for packaging a semiconductor chip, comprising:
providing a semiconductor wafer that has an upper surface and includes a plurality of chip regions, each of the chip regions having a semiconductor unit that includes at least one electrical-connecting pad formed on the upper surface;
farming over the upper surface a photoresist layer to cover all of the chip regions, the photoresist layer being subjected to exposing and developing treatments to form a plurality of pad-exposing holes each of which exposes the electrical-connecting pad of a respective one of the chip regions;
filling a first conductive material in the pad-exposing holes of the photoresist layer, followed by reflowing so as to form the first conductive material into a plurality of first electrical contacts respectively in the pad-exposing holes;
removing the photoresist layer, and forming over the upper surface a protective layer to cover all of the first electrical contacts;
grinding the protective layer until a top end of each of the first electrical contacts is exposed;
coating an insulated protective layer on the ground protective layer, the insulated protective layer being subjected to exposing and developing treatments to form a plurality of via holes to expose the first electrical contacts;
filling a second conductive material in the via holes, followed by reflowing so as to form the second conductive material into a plurality of second electrical contacts that are respectively located in the via holes and respectively connected to the first electrical contacts; and
removing the insulated protective layer.

2. The method of claim 1, wherein the protective layer is made of a transparent material.

3. The method of claim 1, before removing the insulated protective layer, further comprising a step of grinding the insulated protective layer so that a top end of each of the second electrical contacts is flush with a ground surface of the insulated protective layer.

4. The method of claim 1, after removing the insulated protective layer, further comprising a step of cutting the semiconductor wafer into a plurality of semiconductor packages.

5. A method for packaging a semiconductor chip, comprising:
providing a semiconductor wafer that has upper and lower surfaces and includes a plurality of chip regions, each of the chip regions having a semiconductor unit that includes: at least one electrical-connecting pad formed on the upper surface, at least one metal pad formed on the lower surface, and at least one through hole extending through the semiconductor unit to spatially communicate the electrical-connecting pad and the metal pad;
filling a first conductive material in the through hole of the semiconductor unit of each of the chip regions;
performing a reflowing treatment to form the first conductive material into a plurality of first electrical contacts each of which protrudes out of the metal pad of a respective one of the chip regions;
forming over the lower surface a protective layer to cover all of the first electrical contacts;
grinding the protective layer until a lower end of each of the first electrical contacts is exposed;
coating an insulated protective layer on the ground protective layer, the insulated protective layer being subjected to exposing and developing treatments to form a plurality of via holes to expose the first electrical contacts;
filling a second conductive material in the via holes, followed by reflowing so as to form the second conductive material into a plurality of second electrical contacts that are respectively located in the via holes and respectively connected to the first electrical contacts; and
removing the insulated protective layer.

6. The method of claim 5, wherein the protective layer is made of a transparent material.

7. The method of claim 5, before removing the insulated protective layer, further comprising a step of grinding the insulated protective layer so that a lower end of each of the second electrical contacts is flush with a ground surface of the insulated protective layer.

8. The method of claim 1, after removing the insulated protective layer, further comprising a step of cutting the semiconductor wafer into a plurality of semiconductor packages.

9. A method for packaging a semiconductor chip, comprising:
providing a semiconductor wafer that has an upper surface and includes a plurality of chip regions, each of the chip regions having a semiconductor unit that includes at least one electrical-connecting pad formed on the upper surface;
forming over the upper surface a photoresist layer to cover all of the chip regions, the photoresist layer being subjected to exposing and developing treatments to form a plurality of pad-exposing holes each of which exposes the electrical-connecting pad of a respective one of the chip regions;
filling a first conductive material in the pad-exposing holes of the photoresist layer, followed by reflowing so as to form the first conductive material into a plurality of first electrical contacts respectively in the pad-exposing holes;
grinding the photoresist layer until a top end of each of the first electrical contacts is exposed;
coating an insulated protective layer on the ground photoresist layer, the insulated protective layer being subjected to exposing and developing treatments to form a plurality of via holes to expose the first electrical contacts;
filling a second conductive material in the via holes, followed by reflowing so as to form the second conductive material into a plurality of second electrical contacts that are respectively located in the via holes and respectively connected to the first electrical contacts; and
removing the insulated protective layer.

10. The method of claim 9, before removing the insulated protective layer, further comprising a step of grinding the insulated protective layer so that a top end of each of the second electrical contacts is flush with a ground surface of the insulated protective layer.

11. The method of claim 9, after removing the insulated protective layer, further comprising a step of cutting the semiconductor wafer into a plurality of semiconductor packages.

12. A semiconductor package made according to the method of claim 4.

13. A semiconductor package made according to the method of claim 8.

14. A semiconductor package made according to the method of claim 11.

15. A semiconductor package, comprising:
a semiconductor unit including an upper surface and at least one electrical-connecting pad formed on said upper surface;
a protective layer formed an said upper surface of said semiconductor unit, and formed with at least one pad-exposing hole to expose said electrical-connecting pad;
at least one first electrical contact that is received in said pad-exposing hole and that is connected to said electrical-connecting pad; and
at least one second electrical contact formed on said protective layer and immediately above said first electrical contact.

16. The semiconductor package of claim 15, wherein said protective layer is made of a transparent material.
